(19) United States
(12) Patent Application Publication
(10) Pub. No.: US 2024/0310722 A1
(43) Pub. Date: Sep. 19, 2024

(54) METHODS AND APPARATUSES FOR PROCESSING A LITHOGRAPHIC OBJECT

(71) Applicant: Carl Zeiss SMT GmbH, Oberkochen (DE)

(72) Inventor: Michael Budach, Hanau (DE)

(21) Appl. No.: 18/668,793

(22) Filed: May 20, 2024

Related U.S. Application Data
(63) Continuation of application No. PCT/EP2022/082739, filed on Nov. 22, 2022.

(30) Foreign Application Priority Data
Nov. 23, 2021 (DE) 102021213160.3

(51) Int. Cl. G03F 1/74; G03F 1/42; H01J 37/302

(52) U.S. Cl. CPC G03F 1/74; G03F 1/42; H01J 37/3023; H01J 2237/31737; H01J 2237/31742

(57) ABSTRACT

The present invention relates to methods and apparatuses for examining and/or processing a lithographic object, in particular a photomask, with a beam of charged particles in a working region on the object. In addition, the present invention relates to computer programs for controlling such apparatuses to perform such methods.

A method for examining and/or processing a lithographic object, in particular a photomask, with a beam of charged particles in a working region on the object, comprises the following steps: (a.) dividing the working region into a set of partial regions, and (b.) positioning a first quantity of first reference markings over the working region so that the first quantity of first reference markings lie within the working region.

A further method for examining and/or processing a lithographic object, in particular a photomask, with a beam of charged particles in a working region on the object, comprises the following steps: (a.) assigning at least one reference marking from a first quantity of first reference markings, which are distributed over the working region and lie within the working region, to at least one partial region from a set of partial regions into which the working region is divided, and (b.) performing the examination and/or processing of the object in the at least one partial region while taking into account the position of the assigned at least one reference marking.

### CROSS-REFERENCE TO RELATED APPLICATIONS

The present patent application is a continuation of and claims priority under 35 U.S.C. § 120 from PCT application PCT/EP2022/082739, filed on Nov. 22, 2022, which claims priority from German patent application DE 10 2021 213 160.3, entitled “Verfahren und Vorrichtungen zur Untersuchung und/oder Bearbeitung eines Objekts für die Lithographie,” which was filed at the German Patent and Trade Mark Office on Nov. 23, 2021. The entire contents of the above applications are incorporated herein by reference.

### TECHNICAL FIELD

The present invention relates to methods and apparatuses for examining and/or for processing a lithographic or photolithographic object, in particular a photomask, with a beam of charged particles in a working region on the object. The present invention in particular relates to methods and apparatuses for positioning and/or assigning reference markings to a region or to partial regions of the working region to enable drift of the beam of charged particles, for example, during a repair or examination of a defect on the object.

### BACKGROUND

As a consequence of the increasing integration density in the semiconductor industry, photolithography masks (also known as “photomasks,” “exposure masks” or just “masks”) or templates for nanoimprint lithography (referred to as “templates” for short below) need to image ever smaller structures onto wafers. This requires photomasks or templates having ever smaller structures or pattern elements. The production of such photomasks and templates therefore becomes increasingly more complex and as a result more time-consuming and ultimately also more expensive. However, due to the minute structure sizes of the pattern elements, errors during mask or template production cannot be ruled out. These must be repaired, whenever possible.

Errors or defects of photomasks are often repaired, for example, by one or more process or precursor gases being provided at the repair site and the defect being scanned with an electron beam, for example. Even the examination or assessment of such defects typically involves the use of a scanning electron beam.

Photomasks and templates are usually electrically insulating samples. Therefore, scanning with electrons (or other charged particles) can cause electrostatic charging, which unintentionally deflects the electron beam from the intended incidence point. Furthermore, the mask or the template can locally heat up due to the scanning, which brings about a change in the length of the object and thus a relative displacement with respect to the scanning electron beam.

Both effects are manifested in the form of distortions and displacements of a scan region or of an image or writing field of the electron beam, which results in a displacement of the images captured by the electron beam or of the structures written. Moreover, both effects typically result in a distortion of the image or writing field of the scanning electron beam, for example in the form of a change of scale.

The effects of a relative displacement between the mask and the electron beam are often addressed by defining for example a repair relative to a reference marking in the image or scan region of the electron beam, tracking the position of the reference marking for the repair duration by way of image processing methods, and displacing the electron beam for the repair by use of an offset. However, markings or reference markings degrade in the course of a repair process, since they are subject to similar conditions as the defect to be repaired itself is. Therefore, the markings are scanned as infrequently as possible but as often as necessary.

For example, US 2009/0 218 488 A1 describes a method, in which a beam drift is compensated while the beam processes a sample. The beam position is aligned by using a mark that lies close enough to the region to be processed so that the mark can be imaged and the sample can be processed without the need to move the stage (i.e. the table on which the sample is held). During processing, the beam position is corrected with respect to the drift by using a model that predicts the beam drift.

However, in particular when repairing or examining large defects or defects having a large area (e.g. greater than approx. 400×400 nm), the known approaches do not always perform to a satisfactory extent.

First, in the case of such large-area defects, the efficiency of the repair process decreases because the adsorption and diffusion processes of the participating process gases behave differently. In a conventional approach, it is additionally necessary even for such large-area defects—since the process time increases as the size increases—for the reference marks to be scanned more often, and as a result they degrade more. A reference mark that is degraded in this way causes greater noise in the position determination and consequently negatively affects the quality of the repair or even causes it to be stopped. Furthermore, the distance of the reference marks from the critical edges (or other relevant structures) of the mask or the template increases. As a result, the accuracy of the edge positioning is decreased because nonlinear influences increase due to the charging.

The present invention is therefore based on the general aspect of specifying methods and apparatuses that provide improved possibilities for examining and/or processing lithographic objects, in particular for examining and/or processing large-area defects on such objects (e.g., having a diameter of greater than a few 100 nm).

### SUMMARY

This general aspect is at least partially achieved by the various aspects of the present invention as they are defined in the appended independent claims. Further possible embodiments of these invention aspects are stated in the dependent claims.

A first aspect of the invention is provided by a method for examining and/or processing a lithographic object, in particular a photomask, with a beam of charged particles in a working region on the object, which in one embodiment comprises the following steps: (a.) dividing the working region into a set of partial regions; and (b.) positioning a first quantity of first reference markings over the working region so that the first quantity of first reference markings lie within the working region.

In particular, the method can be used for examining and/or repairing defects of the object, in particular mask defects. Such defects represent deviations of the mask or the object from corresponding target values. Typical mask defects are sites or regions in which too much or too little absorber material is present and which are addressed for example by local etching or material deposition with the aid of an electron beam or particle beam while introducing corresponding precursor gases.

The working region is the region of the object that is intended to be examined or processed in one procedure.

As part of the present disclosure, the working region can in particular represent a region of the object that is intended to be examined/processed uniformly, that is to say a region that is not examined or processed in procedures that can be considered to be independent of one another. The working region of a photomask is in particular a local region that does not encompass the entire photomask. The working region can thus represent or include for example a local defect that does not break up into a number of completely separate partial defects or can be subdivided into completely separate partial defects. A “local” defect can here mean in particular: small compared with the size of the object, e.g. the mask. For example, the working region or the defect contained therein can have one or more lateral extents of smaller than 1 mm, smaller than 100 μm, smaller than 10 μm, smaller than 2 μm, smaller than 1 μm, or smaller than 500 nm. The working region or the local defect could fit, for example, into an (imaginary) square having side lengths of 1 mm, 100 μm, 10 μm or 2 μm or 1 μm or 500 nm.

The working region can here be delimited by a circumferential periphery or a contour line, and everything within this periphery or within this contour line can be considered to be part of the working region. In figurative terms, imagine a “lasso” that is thrown for example around a defect and tightened until it has “captured” the defect at the minimum length. The “lasso” then represents the outer periphery of the working region (alternatively, one might also consider an elastic band that is thrown around the defect and pulled tight around it, wherein the band would then define, due to its width (e.g. a width in the range of typical diameters of the reference markings discussed here), a peripheral strip around the working region rather than a linear periphery).

In principle, gaps (e.g. in the form of holes or interruptions) in which no examination/processing takes place or is intended, or takes place or is intended only to a smaller extent, may also be present in the working region. The working region can be formed, for example, by a defect or by a group of defects that have gaps in which no examination/processing takes place or is intended, or in which examination/processing takes place or is intended only to a smaller extent.

With reference to the above analogy of capturing with a lasso, the working region (or the defect(s) forming it) can be described or defined such that it has no gaps in which no examination/processing takes place or is intended, or in which examination/processing takes place or is intended only to a smaller extent, “along the tightened lasso,” that is to say along its (outer) circumferential periphery.

However, it can also be described or defined such that it merely substantially has no gaps, that is to say is substantially free from gaps, in which no examination/processing takes place or is intended, or in which examination/processing takes place or is intended only to a smaller extent, along its (outer) circumferential periphery. The working region or the periphery thereof can be referred to here for example as being “substantially” free from gaps if the gaps (each individually or in sum) take up less than 20%, less than 10%, less than 5%, less than 2% or less than 1% of the overall circumference of the working region, wherein the overall circumference can be understood to mean the entire length of the periphery. Alternatively or additionally, the periphery of the working region can be referred to as being free from gaps even if, for example, the gaps (each individually or in sum) are smaller than 50 nm, smaller than 20 nm, smaller than 10 nm, smaller than 5 nm, smaller than 2 nm or smaller than 1 nm, wherein the size of the gaps can be understood and determined as being the extent thereof along a “tightened lasso” around the working region. The gaps that are permissible can thus be “small” (for example in the meaning of the word “small” that will be explained below) in relation to the overall circumference of the working region. A working region can consequently enclose, for example, a defect that has such “small” gaps or even a group of defects between which such “small” gaps are disposed.

To illustrate this, reference is already made at this point to the detailed discussion relating to FIGS. 5A to 5C further below. For example, a defect in the form of excess absorber material or foreign material may be present, for example, on a lines-and-spaces structure over several 100 nm, wherein more material needs to be removed in the regions of the spacers than in the regions of the lines, where perhaps less material or possibly even no material at all needs to be removed, in order to successfully eliminate the defect. However, if the entire extent of the defect is processed in one connected repair process that can be considered to be a unit, the entire defect (or the entire surface area over which the excess absorber material or foreign material extends) can define the working region of the object with respect to this repair. Moving along the periphery of said working region, there will be, at the place where lines that do not need to be processed intersect the periphery, in each case a gap in the periphery of the working region (since no processing takes place here). However, since an individual line has a width that is small compared with the overall extent of the defect, typically a few nanometers, the periphery in that case can still be referred to as “substantially” free from gaps.

To further an even narrower understanding, the working region can also be described or defined such that it substantially has no gaps, that is to say is substantially free from gaps in which no examination/processing takes place or is intended, or in which examination/processing takes place or is intended only to a smaller extent, that is to say also in its interior and not just along its periphery. Alternatively, the working region can be described or defined such that it is entirely free from such gaps.

When considering for example an annular region to be examined or processed with a large hole in the center, or a region that is topologically equivalent, i.e. homoeomorphic, to such an annular region, then according to the broader understanding of the working region in the sense of: “Everything that is captured by the lasso” set forth in the introductory part, the hole would also be able to be considered as part of the working region. However, according to the narrower understanding mentioned here, this hole could not be considered to be part of the working region, at least unless it can be understood to be “small” in the meaning that will be discussed in short order.

For example, the working region can be understood to be, substantially free from gaps if any gaps that are present (for example holes, interruptions) are “small” with respect to the overall extent or overall surface area of the working region. “Small” in this context can mean for example: the holes, gaps or interruptions take up (each individually or in sum) less than 20%, less than 10%, less than 5%, less than 2% or less than 1% of the overall surface area of the working region. “Small” can also mean, for example: the holes, gaps or interruptions have (each individually or on average) an extent, determined for example as the greatest lateral extent thereof or alternatively as the smallest lateral extent thereof, of smaller than 50 nm, smaller than 20 nm, smaller than 10 nm, smaller than 5 nm, smaller than 2 nm or smaller than 1 nm. “Small” can also mean: having a smaller extent than the structures to be examined or processed of the object themselves.

In summary, once again it should be emphasized that, within the meaning of the present invention, the working region can be defined in particular by the extent of an individual, connected (e.g. path-connected or simply connected) defect, although not necessarily including “small” holes, gaps or interruptions in the sense explained above, but by the extent of a large-surface, connected defect (for example a few 100 nm in length/width or diameter), and such defects represent an important use scenario of the present invention with its various aspects. A working region and/or connected defect can have, for example, a lateral extent that exceeds at least in one direction 50 nm, 100 nm, 200 nm, 300 nm, 400 nm or 500 nm. The working region and/or connected defect can also have lateral extents in two spatial directions that are perpendicular to each other, which lateral extents exceed the limits mentioned in the previous sentence. However, at the same time it can be a “local” defect or working region in the sense defined above.

As a final note on the subject, reference is made to the fact that the following text will also describe how specific reference markings (specifically those of a second quantity) can also be positioned outside the working region and be written there onto the object. However, since these reference markings serve for process control and do not represent the actual features of the object that are to be examined or repaired, they are not counted as belonging to the working region. They therefore lie outside the working region, even if they are used in the method as comparison markers. To this extent, for example writing these reference marks and determining the position thereof is not inconsistent with the statements made above.

According to the method described here, the working region is split into a set of partial regions, i.e. preferably into two or more partial regions. However, in principle an application of the invention in only one (partial) region is also conceivable. For linguistic convenience, the following text will always refer to “the partial regions”—in the plural. Where it will aid clarity of the illustration, the partial regions will be numbered below with the variable i∈ [symbol] , wherein, if the working region is divided into N partial regions, i∈{1, 2, . . . , N}. As was already just mentioned, preferably N≥2, but N=1 is also conceivable.

The working region can be divided into partial regions depending on various criteria. For example, the partial regions can be selected such that they all have the same, or at least approximately the same, surface area (e.g. within a certain tolerance, for example 5% or 10% of its average surface area), do not exceed a specific surface area, do not fall below a specific surface area, or arise from the topology of the entire defect. These criteria can also be combined with one another. Additionally, depending on the type of the repair process to be used (e.g. etching material or depositing material, etc.), a different criterion or a different combination of criteria can be decisive.

The examination or processing can then take place in each of the partial regions for example in a manner such that the electron or particle beam is scanned over the partial region along a specific pattern, also referred to as “(repair) shape”, and thereby carries out or induces the examination or processing in a manner known per se. The pattern or the shape can correspond here for some or all of the partial regions, or it can be individually determined for individual, some or all partial regions. The patterns or shapes can be known in advance, for example from the examination or processing of small object regions or defects of approximately the same size as the partial regions.

Additionally, a quantity of reference markings are positioned over the working region such that they lie within the working region (that is to say the reference markings contained in the quantity lie within the working region). To avoid ambiguity, this quantity will be referred to as the first quantity of first reference markings so as to be able to differentiate it from the (optional) second quantity of second reference markings, which lie outside the working region and will be described in more detail below.

Any given reference marking can here be understood to “lie within the working region” if it lies at least partially within the working region (a reference marking will, after all, generally have a certain spatial extent and cannot be considered to be a point). However, the preferred meaning of “lie within the working region” is that the corresponding reference marking lies completely in the working region.

At this point, it should be noted that the first quantity can in this case also contain only a single element, that is to say a single first reference marking. However, for linguistic convenience, the following text will always refer to “the first reference markings”—that is to say in the plural. In addition, the case of a plurality of first reference markings, that is to say at least 2, is actually preferred. In the same way, the second quantity that was already briefly mentioned can also contain only a single element, that is to say a single second reference marking. In this context, the following text will for linguistic convenience again always refer to “the second reference markings”—that is to say in the plural, even though the singular is included herein. However, once again the case of a plurality of second reference markings, that is to say at least 2, is preferred.

Positioning this first quantity of first reference markings “in the interior of the working region” enables in particular the examination or processing of large-area defects without the typically associated difficulties described in the introductory part, because the reference markings move closer to the instantaneous point of incidence of the electron or particle beam while said beam scans over a specific partial region for examining or processing the latter. This can be advantageously utilized for example in a manner such that, when a specific partial region is examined or processed without the stage being moved, a first reference marking always lies in the image field or writing field of the beam and can serve as a position reference for compensating for any beam drift. Since there is no need to displace the stage back and forth for this purpose, as may otherwise be the case for example when processing the center of a large defect, it is possible to save time and, additionally, the potential error sources with respect to the exact determination of the actual beam position can be reduced.

The first reference markings of the first quantity are preferably positioned here at such sites within the working region where they will have substantially no influence and/or the smallest influence on the performance (i.e. for example the desired imaging behaviour of the mask or the template) and/or on the intended examination and/or processing. For lines-and-spaces structures, for example, the lines may be preferred as the locations for the first reference markings, while the spaces are avoided because they can generally have a greater (unintended) effect on the imaging behaviour of the mask or template in the spaces.

Besides the positioning of the reference markings, another aspect is generally also important here, which will likewise be addressed by the present invention. This is the assignment of the reference markings to the individual partial regions, which can be understood to mean for example a provision specifying which reference marking or markings should be used as a comparison marker or position reference for the examination or processing of a given partial region. In other words, the position of the reference markings primarily deals with the question of where on the object they should lie or be attached, and the assignment deals with the question of which of the reference markings is or are “responsible” for which partial region.

A person skilled in the art recognizes that there is interplay here between the division of the working region into the partial regions and the positioning of the reference markings (and in particular the total number of the first reference markings that are necessary or desired) and also the positioning of the reference markings and the assignment thereof to the partial regions. Some aspects of these relationships will be described in more detail below with reference to specific examples.

At any rate, the method may comprise for at least one partial region of the working region, preferably for each partial region of the working region, assigning at least one reference marking from the first quantity to the respective partial region.

Here, the same number of first reference markings (i.e. one, two, three, four, etc.) can be assigned to each of the relevant partial regions (i.e. to one, some or all partial regions), or the number can fluctuate over the relevant partial regions. For example, it is possible to assign fewer first reference marks in each case to a partial region or partial regions that lie “at the periphery” of the working region than to a partial region or to partial regions that lie “in the center” of the working region, which can be compensated for by the fact that such peripheral partial regions can also be assigned additional, second reference markings from a second quantity located outside the working region (more on this below).

It should further be noted that a given reference marking (be it a first reference marking from the first quantity or a second reference marking from the second quantity, which will be described in more detail below) can be assigned to a plurality of partial regions (for example to a partial region to the left of it and to a partial region to the right of it, etc.).

The method can furthermore comprise writing the first quantity of first reference markings onto the object, preferably by use of the beam of charged particles.

The positioning of the first reference markings described above can initially be understood in purely conceptional terms in the sense that suitable positions for the first reference markings are determined without them being physically written onto the object (the writing may also take place for example separately, in an independent method). However, this writing of the reference markings is preferably effected as part of the method itself, since this enables error sources and inaccuracies to be minimized, which could otherwise be caused for example by clamping and releasing the object in suitable holders or stages multiple times.

For the writing itself, the same particle or electron beam can be used that is also used for the examination or processing itself, which may likewise aid in minimizing error sources and inaccuracies. However, this is not absolutely necessary, and a separate particle or electron beam may also be used for the writing.

The method can furthermore comprise, as already indicated above, positioning a second quantity of second reference markings on the object, with the result that the second quantity of second reference markings lie outside the working region (that is, the second reference markings lie outside the working region).

It should be noted here as a peculiarity that a somewhat greater freedom may exist when positioning the second reference markings than for the first reference markings because the second reference markings do not lie within the working region of the object. Depending on where on the object the working region is located and what its environment looks like, when positioning the second reference markings, for example their effect on the performance or the imaging behaviour can therefore be less severe, meaning that there may be more leeway here (for example when a mask periphery that does not contribute to the actual lithographic imaging can be used for positioning the second reference markings).

For at least one of the partial regions of the working region, or for a plurality of or, in the extreme case, even all partial regions, the method can then further comprise assigning at least one reference marking from the second quantity to the respective partial region.

Such second reference markings can complement the first reference markings “in the interior” of the working region, if necessary, so that for example when examining or processing peripheral regions of the working region, sufficient reference markings will be available there, too, at a suitable distance.

The method can also comprise writing the second quantity of second reference markings onto the object, preferably by use of the beam of charged particles.

Analogous statements made above in connection with the writing of the first reference markings apply here.

As far as the assignment of the (first and/or second) reference markings is concerned, the method can comprise, for at least one of the partial regions of the working region, but preferably for all partial regions of the working region, assigning the m closest reference markings to the respective partial region. Here, preferably, m=3, with particular preference m=4.

Which ones are the m closest reference markings of a given partial region can be determined here for example using the following (conceptional) procedure: Proceeding from a specific reference point in the partial region, a circle is drawn around this point, whose radius r is increased until m reference markings (from the first and/or second quantity) fall into the interior of the circle. The reference point selected can here be for example the center point of the corresponding partial region (or another unambiguously determinable point), wherein the center point can be defined, for example, as the centroid of an area that corresponds to the partial region in terms of its shape.

Besides a circle, the illustrated procedure for determining the closest reference markings can also take place with the aid of a different geometric shape, for example with the aid of a square aligned with the object peripheries (for example the mask or template peripheries).

Translated into a mathematical language, this can be understood to mean that, proceeding from the suitably defined reference point, within the respective partial region (for example its center point or centroid in the sense mentioned above), for determining the m closest reference markings, a distance term d is used that is known to a person skilled in the art as p-norm, wherein p can take values ranging from 1 to ∞ and is defined for a distance vector d=(x,y) in 2 dimensions as follows:

$$d = \sqrt[p]{{\vert x \vert}^{p} + {\vert y \vert}^{p}} .$$

The case p=2 corresponds to the abovementioned case of using a circle, and the case p=∞ corresponds to the specified case of using a square.

The magnitude of m will be dependent here on how high the desired accuracy of the positioning is and how important the efficiency or speed of the method is. The distance between the reference markings (for example a typical or mean distance between them) and the relationship of this distance to a size of the partial regions (for example a typical or average size of the partial regions) can also have influence on a suitable selection of m (this similarly also applies to the variable, which will be described in more detail below). The use of a larger value for m will make the method generally more accurate but also slower.

However, choosing m=3, better yet m=4 (or even greater), can be advantageous because it can also enable the detection of distortions of the image region, which is not possible for example when using only two reference markings (m=2) because in that case, only distance changes can be determined.

Furthermore, the value m could also vary between different partial regions and, for example, could be selected to be larger for partial regions having a more complex structure than for partial regions having a less complex structure.

A constant value for m over the relevant partial regions may be advantageous, however, since this can enable the advantageous use of certain symmetry properties (for example in conjunction with suitable positioning of the reference markings; cf. below in this respect).

In particular, for each of the partial regions to which its m closest reference markings are assigned in this way, at least one of the assigned m closest reference markings can come from the first quantity of first reference markings located within the working region.

For at least one of the partial regions of the working region, but preferably for all partial regions, the method can also comprise, in addition to assigning the m closest reference markings, assigning the n second closest reference markings to the respective partial region. In this case, preferably n=3, with particular preference n=4.

In other words, the relevant partial regions (i.e. one, some or all partial regions of the working region), can be assigned two “layers” of reference markings, specifically the m closest reference markings as the first layer and the n second closest reference markings as the second layer. The various layers can be used for example to detect or compensate for different position errors or distortion errors of the beam optical unit. The first layer can mainly serve, for example, for detecting lateral displacements and the second layer for detecting distortions, or the like.

The reference markings of the various layers can here certainly be “consulted” with various frequencies during the procedure, for example their actual position can be compared to a target position, for example that of the first layer more frequently than that of the second layer, or vice versa.

The determination of the n second closest reference markings to the respective partial region can here be done analogously to the determination of the m closest reference markings. The use of a different distance term for determining the second closest reference markings (for example a different p-norm) would also be conceivable, however, in order to obtain a different symmetry characteristic for the reference markings of the second layer in comparison with the first layer (again in interplay with suitable positioning of the reference markings).

For example, positioning the first quantity of first reference markings and/or the second quantity of second reference markings can be done in accordance with an at least approximately regular, two-dimensional grid.

“At least approximately regular” can mean, for example, regular except for deviations that are not noticeable in comparison with the (for example mean or minimal) distance between the reference markings (for example deviations of less than 20%, or less than 10%, or less than 5%, or less than 2%, or less than 1% of the distance between the reference markings).

The grid can be formed for example from rectangles or squares or from triangles (for example isosceles or equilateral) or from other regular polyhedrons. A different type of tessellation of the plane is also encompassed.

At any rate, it is possible by way of the regularity of the grid to impress onto the positioning or distribution of the reference markings specific symmetry properties which can be used advantageously for detecting positioning errors/imaging errors of the particle beam, since symmetric arrangements are particularly “strict” and deviations can therefore be easier to detect than may be the case in different types of arrangement of the reference markings.

In particular, a unit cell of the grid can represent an m-gon, with the variable m here being the same as the abovementioned number of closest reference markings to the corresponding partial regions.

For example, if the object or working region is covered with first and possibly second reference markings according to a pattern based on equilateral triangles and if each partial region (or at least some partial regions or only one particularly “interesting” partial region) is assigned the m=3 closest reference markings, it is possible under certain conditions (for example if the distance between the reference markings of one triangle is not too great in comparison with the size of the partial regions) from the knowledge of the triangle arrangement thereof to particularly easily draw conclusions relating to the imaging, distortion or position errors of the particle beam. Possibly, for example, the n=3 or n=6 second closest reference markings can likewise be used for this purpose, i.e. be assigned to the corresponding partial region, in order to increase the available information content even further and/or to enable extrapolation of the beam behaviour or beam drift even beyond the instantaneous image/writing region.

A second aspect of the invention is provided by a method for examining and/or processing a lithographic object, in particular a photomask, with a beam of charged particles in a working region on the object, which in one embodiment comprises the following steps: (a.) assigning at least one reference marking from a first quantity of first reference markings, which are distributed over the working region and lie within the working region, to at least one partial region from a set of partial regions into which the working region is divided; and (b.) performing the examination and/or processing of the object in the at least one partial region while taking into account the position of the assigned at least one reference marking.

In an example, a method according to the second aspect may comprise a method for processing a defect of a lithographic object, in particular a photomask, with a beam of charged particles in a working region on the object, comprising: a.) dividing the working region into a set of two or more partial regions; b.) assigning at least one reference marking from a first quantity of first reference markings for the object to at least two partial regions from the set of two or more partial regions; wherein to one of the at least two partial regions (wherein the term region may also be termed area herein) at least one other reference marking is assigned than to another of the at least two partial regions; c.) performing the processing of the object in the at least two partial regions while taking into account the position of each of the assigned at least one reference marking.

In an example, the working region may comprise a first partial region and a second partial region, wherein the second partial region is adjacent to the first partial region. For example, adjacent may comprise that the first partial region may share a border with the second partial region over a certain distance.

For example, the dividing may comprise dividing the working region into the set of two or more partial regions such that the working region comprises the first partial region and the second partial region (as described herein).

In another example, the dividing may comprise that all partial regions of the set of two or more partial regions may be positioned in a coherent (or contiguous) manner such that any partial region may be adjacent to at least one other partial region of the set of two or more partial regions.

In an example, the assigning may comprise assigning a first reference marking from the first quantity to the first partial region and a second reference marking from the first quantity to the second partial region. In this example, the first reference marking may be a different reference marking than the second reference marking. Hence, one of the at least two partial regions at least one other reference marking is assigned to than to another of the at least two partial regions.

In an example, the first quantity of first reference markings may be positioned over the working region and may lie within the working region.

In an example of the method according to the second aspect, the working region may be defined substantially by an extent of the defect and (e.g. the working region or the defect) can comprise one or more gaps in which processing may take place to a smaller extent or no processing is intended (as described herein).

This second aspect of the invention intersects with the first aspect in the assignment of the first reference marking(s) to one or more of the partial regions (e.g., to two or more partial regions) of the working region. Accordingly, unless obviously contradictory, all statements made regarding the possible embodiments of the method of the first aspect also apply to the embodiments of the method of the second aspect which will now be discussed—and vice versa—even if this is not explicitly mentioned again for all variants and options. This concerns in particular the understanding of the working region and the assignment of the reference markings to the partial regions.

However, it is emphasized here that it is possible as part of the method of the second aspect discussed here to use already existing reference markings—be it in the form of dedicated markers on the object or in the form of other existing object/mask structures that can serve as reference markings—and that the positioning and in particular the writing of the first and/or second reference markings onto the object does not represent a necessary part of the method of the second aspect described here.

The “reference markings assigned to the respective partial region” are here those reference markings (or is that reference marking; it should be remembered that when it comes to the reference markings, the singular is always included, even if this is not expressly mentioned otherwise) that are used in the examination or processing of the relevant partial region in the method (for example as a reference or comparison marker for determining any beam drift), specifically independently of the quantity of reference markings to which they belong.

According to the embodiment of the method of the second aspect just mentioned, a reference mark “from the interior” of the working region, i.e. a first reference mark from the first quantity, must be assigned here to at least one partial region. Different reference marks can be allocated or assigned to the other partial regions.

As already mentioned, the use of such first reference markings located in the interior are advantageous in particular when examining or processing large-area defects or structures (e.g. having a diameter of greater than a few 100 nm) because stage movements for position comparison can be avoided, since reference points are not only present around the working region but also in the interior thereof. This may initially entail a certain amount of additional effort in the sense that the positioning of the first reference marking within the working region will possibly have to be planned and considered more accurately, as was already mentioned further above, because they may have a possibly quite significant, unintended influence on the performance of the object (e.g. the imaging properties of a mask) and/or the examination or processing thereof itself. This additional effort that may occur then, however, pays off with a greater accuracy and efficiency during the examination or processing itself.

Preferably, at least one reference marking from the first quantity, i.e. at least one reference marking “from the interior” of the working region, is then assigned to a plurality of partial regions, with particular preference to each partial region, from the set of partial regions in step a., and the method further comprises performing the examination and/or processing of the object in the relevant partial regions while taking into account the position of the at least one first reference marking assigned to the respective partial region (and possibly further first and/or second reference markings assigned to the respective partial region).

The method can furthermore comprise dividing the working region into the set of partial regions (preferably two or more partial regions; an individual region is also included, however, as already mentioned).

The method can likewise comprise positioning the first quantity of first reference markings over the working region. Additionally, the method can comprise writing the first quantity of first reference markings onto the object, preferably by use of the beam of charged particles.

Dividing, positioning and/or writing can also be part of the method described here according to the second aspect itself. However, dividing, positioning and/or writing can also be done in a separate method, and the method described here then uses the result of said other method, that is to say, reference markings which are already positioned/written can also be used, as already mentioned.

For example, dividing, positioning and/or writing can be performed as part of an embodiment of the method already described according to the first aspect, where these steps or possibilities have already been discussed in detail. For the sake of conciseness, reference is therefore also made to the corresponding statements in connection with the method of the first aspect to avoid unnecessary repetition, while emphasizing that the statements made there also apply to the dividing, positioning and/or writing of the first quantity of first reference markings as part of the method of the second aspect.

The method of the second aspect discussed here can furthermore comprise the following steps for at least one of the partial regions of the working region: assigning at least one reference marking from a second quantity of second reference markings to the respective partial region, wherein the second quantity of second reference markings lie outside the working region (i.e. the second reference markings lie outside the working region), and performing the examination and/or processing of the object in the respective partial region while also taking into account the position of the at least one second reference marking assigned to said partial region.

The advantages of such second reference markings (as always, the singular is included), for example to complement the first reference markings in particular for a peripheral partial region or partial regions, have already been emphasized above (in connection with the method of the first aspect), and reference is also therefore made in this respect to the above so as to avoid unnecessary repetitions.

The method can accordingly also comprise positioning the second quantity of second reference markings on the object and/or writing the second quantity of second reference markings onto the object, preferably by use of the beam of charged particles.

Here, too, it is alternatively possible that, rather than performing one or both of the steps in the present method itself, the result of a separately performed method is used, for example the result of an embodiment of the method of the first aspect as described above, that is to say reference markings which are already positioned/written can be used here as well, as part of the method of the second aspect. With respect to further details, reference is again made to the above for the sake of conciseness.

Again as part of the method of the second aspect described here, for at least one of the partial regions of the working region, but preferably for each of the partial regions of the working region, assigning can comprise assigning the m closest reference markings to the respective partial region, wherein preferably m=3, with particular preference m=4.

Here, for each respective partial region, at least one of the assigned m closest reference markings can stem from the first quantity of first reference markings located within the working region.

Furthermore, the method for at least one of the partial regions of the working region, preferably for all partial regions, can comprise assigning the n second closest reference markings to the respective partial region, wherein preferably n=3, with particular preference n=4.

Positioning the first quantity of first reference markings and/or the second quantity of second reference markings can also be performed or have been performed in accordance with an at least approximately regular, two-dimensional grid. A unit cell of the grid can represent an m-gon, for example.

These possibilities and the associated preferences have already been comprehensively explained as part of the first aspect of the invention, and since the statements made there also apply here as part of the second aspect, reference is again made to the above statements relating to these possibilities for the sake of conciseness.

As part of the method described here (but generally also as part of the method of the first aspect described above), the position of the reference marking(s) assigned to a respective partial region can now be taken into account such that it serves for compensating for any drift of the beam of charged particles during the examination and/or processing of the partial region.

Compensating for the drift can thus comprise comparing a measured position of a respective reference marking with a target position of said reference marking.

Depending on the number of (first and/or second) reference markings assigned to a given partial region, information relating to various aspects of beam drift are available during the examination or processing of said partial region, for example lateral displacements, image/writing field distortions or image/writing field misalignment such as rotations. Depending on how many of these error components are intended to be considered or monitored and possibly compensated for, an appropriate number of reference markings will be assigned to the partial region and the determined positions thereof will be compared with their target positions.

If a specific reference marking has been identified as being degraded, it is additionally possible to re-assign the reference markings by excluding the degraded reference marking for the partial region or regions of the working region that was/were assigned the degraded reference marking.

As already mentioned in the introductory part, the reference markings generally are subject to the same or at least similar conditions as the object to be examined or processed itself. This is true in particular for the first reference markings located in the working region. For this reason, the method provides the possibility of replacing reference markings that have degraded too much with others, wherein it is advantageous that reference markings are arranged not only around the working region but also in the interior thereof, as a result of which suitable “replacement markings” are generally available in the local environment (that is to say for example at a suitably small distance in order to avoid or minimize the need for stage movements).

Identifying the degradation of a marking can be performed for example via a loss of contrast of the marking in an image thereof.

For example, for each of the relevant partial regions, the degraded reference marking can be replaced by the respectively closest reference marking (be it from the first quantity or the second quantity) that was not already assigned to the respective partial region.

The degraded reference marking can thus be replaced by the “next best” available reference marking so that the number of the reference markings assigned to the relevant partial region remains the same, with the result that the available information content relating to the various error components of potential incorrect beam positioning remains intact and they can therefore continue to be monitored and possibly compensated.

The possibilities just discussed relating to the replacement of degraded reference markings with other ones can additionally also already be used “proactively” in order to avoid that a noticeable or excessive degradation of the reference marking occurs in the first place.

For example, if a specific condition relating to a specific reference marking occurs (for example that said reference marking has already been used for a certain period of time, or the like), the reference markings can be re-assigned by excluding the relevant reference marking for the partial region or regions of the working region to which the relevant reference marking was assigned. For example, for each of the relevant partial regions, the relevant reference marking can be replaced by the respectively closest reference marking (be it from the first quantity or the second quantity) that was not already assigned to the respective partial region.

Such a re-assignment or re-allocation can be performed for example cyclically with specific (predefined) time spans, which can also serve to avoid or reduce systematic errors.

A third aspect of the invention is provided by an apparatus for examining and/or processing a lithographic object, in particular a photomask, with a beam of charged particles in a working region on the object, which in one embodiment comprises the following: (a.) means for dividing the working region into a set of partial regions; and (b.) means for positioning a first quantity of first reference markings over the working region so that the first quantity of first reference markings lie within the working region.

The apparatus can be configured in particular to perform one of the possible embodiments of the method according to the first and/or second aspect of the invention described above.

A fourth aspect of the invention is provided by an apparatus for examining and/or processing a lithographic object, in particular a photomask, with a beam of charged particles in a working region on the object, which in one embodiment comprises the following: (a.) means for assigning at least one reference marking from a first quantity of first reference markings, which are distributed over the working region and lie within the working region, to at least one partial region from a set of partial regions into which the working region is divided; and (b.) means for performing the examination and/or processing of the object in the at least one partial region while taking into account the position of the assigned at least one reference marking.

The apparatus can be configured in particular to perform one of the possible embodiments of the method according to the first and/or second aspect of the invention described above.

A fifth aspect of the invention is provided by a computer program which, in one embodiment, comprises commands that, when they are executed, cause one embodiment of the apparatus according to the third aspect of the invention to perform the method step of an embodiment of the method according to the first aspect, or cause an embodiment of the apparatus according to the fourth aspect of the invention to perform the method steps of an embodiment of the method according to the second aspect.

### BRIEF DESCRIPTION OF THE DRAWINGS

The following detailed description describes technical background information and exemplary embodiments of the invention with reference to the Figures, in which:

FIG. 1 illustrates an aspect of the problems that arise when examining and/or processing a photolithographic object with an electron beam, wherein the element has a charged surface.

FIG. 2 schematically illustrates a top view of an exemplary repair situation of the defect of a photolithographic mask as described in the prior art.

FIG. 3 schematically shows compensation of the drift of an electron beam with respect to a marking caused by an electrostatic charge, according to the prior art.

FIG. 4 reproduces displacements of a marking with respect to an x-axis and a y-axis during the repair of the defect of FIG. 2.

FIGS. 5A-5C show the examination and/or processing of large-area defects. FIG. 5A here exemplifies a few of the problems that occur in the prior art methods. FIGS. 5B and 5C illustrate different aspects of the present invention that eliminate said problems.

FIG. 6 finally schematically shows a few components of an apparatus for performing a method according to the invention.

### DETAILED DESCRIPTION

Some technical background information and possible embodiments of methods and apparatuses according to the invention are explained in greater detail below on the basis of the examination of a photolithographic mask and the processing of a defect of a photolithographic mask.

The methods and apparatuses according to the invention can be used initially for examining and/or processing all types of transmissive and reflective photomasks. Furthermore, the methods and apparatuses according to the invention can also be used for examining and/or processing templates for nanoimprint lithography and/or wafers. The methods and apparatuses according to the invention of furthermore are not even limited in principle to the examination or processing of (photo)lithographic objects. Rather, they can be used generally for analyzing and/or processing an electrically non-conductive or only poorly conductive sample with a charged particle beam.

To aid clarity and avoid ambiguity, however, the embodiments that follow will involve throughout the example of a photolithographic mask, although the other possible uses of the described invention aspects are always encompassed thereby and should therefore also always be taken into account.

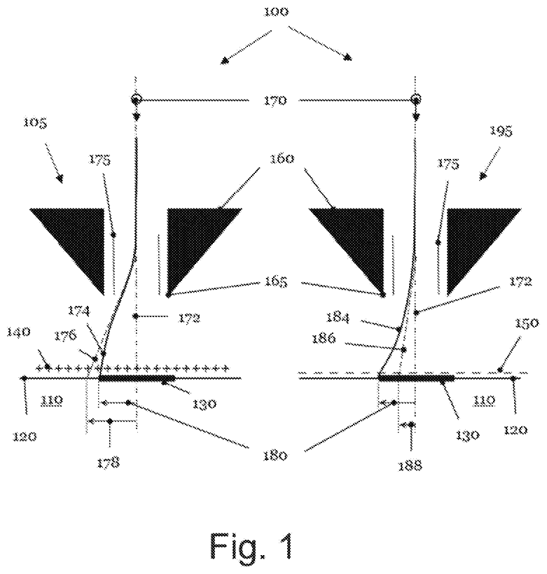

The diagram 100 in FIG. 1 shows a schematic section through a charged mask 110 and an output 165 of a scanning electron microscope 160. The mask 110 has on its surface 120 a distribution of surface charges that cause an electrical potential distribution or an electrostatic charging of the mask 110. On the left image part 105, the mask surface 120 has a positive charge 140. In the right image part 195, the mask surface 120 shows an excess of negative charges 150. The reference signs 140 and 150 are used hereinafter to denote both a distribution of surface charges on a mask surface 120 and also the electrical potential distributions caused by the charged surfaces.

An electrical charge 140, 150 of a mask surface 120 can be caused by a beam of charged particles 170, for example an electron beam 170 of a scanning electron microscope (SEM) 160. Electrostatic charging 140, 150 of a mask surface 120 can be caused by the scanning of the mask 110 as part of an examination process or can arise as a result of a processing process. For example, electrostatic charging can be caused when processing the mask 110 with an electron beam or ion beam. Furthermore, electrostatic charging 140, 150 of a mask 110 can be caused for example by the handling of the mask 110.

In the portion of the mask 110 that is illustrated in the diagram 100 in FIG. 1, the distribution of the surface charges 140, 150 has a uniform density. However, this is not a condition necessary for the explanations made herein.

In the example in FIG. 1, a deflection system 175 deflects the electron beam 170 and scans it over the mask surface 120 in order to determine the dimensions of the structure element 130 of the mask 110. By way of example, a structure element 130 can be a pattern element of an absorber structure of the mask.

As is illustrated in the left image part 105 of the diagram 100, as a result of the attractive effect of a positive charge 140 of the mask surface 120, an electron beam 170 scanning the structure element 130 is deflected in the vicinity of the mask surface 120 in the direction of the optical axis 172 and follows the trajectory 174. Without the electrical potential distribution 140, the electron beam 170 would follow the path 176. In an SEM image generated by the electron beam 170, the scanned dimension 178 appears larger than the actual dimension 180 of the structure element 130.

By analogy, the right image part 195 in FIG. 1 illustrates the repellent effect of a negatively charged 150 mask surface 120 on the path movement 184 of the electrons 170 of an electron beam 170. Without the electrical potential distribution 150, the electron beam 170 would follow the path 186. As a result of the additional deflection of the electron beam 170, which is directed away from the beam axis 172, in the vicinity of the mask surface 120 as a consequence of the electrostatic charge 150, the measured dimension 188 of the structure element 130 in an SEM image generated from the scanning data appears to have a smaller dimension than the actual dimension 180 of the structure element 130.

The scanning of the structure element 130 by use of an electron beam 170 or more generally with the aid of a charged particle beam 170 can result in local heating of the mask 110 and thus in a change in the extent of the mask 110. Even if these changes in the length of a mask 110 lie merely in the nanometer range, these changes should be taken into account in a processing process of a mask 110 in order not to jeopardize the success of the processing process. Moreover, it is possible for thermal effects of the SEM 160 and/or of the mask 110 or the sample mount (not illustrated in FIG. 1) to cause the point of incidence of the electron beam 170 on the mask 110 to drift as a function of time once again in the two-digit nanometer range.

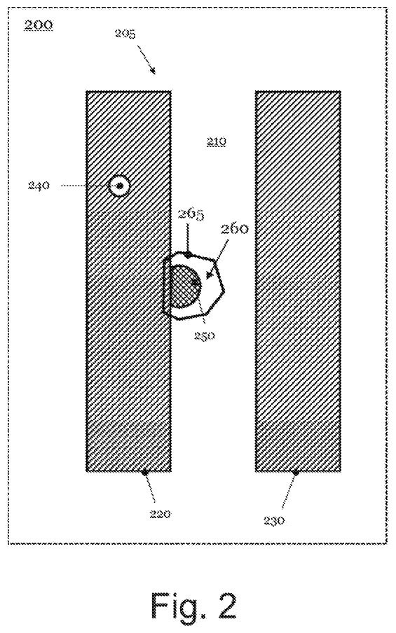

FIG. 2 shows a portion of a top view of a mask 200. This can be the mask 110 in FIG. 1, for example. The photomask 200 comprises a substrate 210. Two pattern elements 220 and 230 in the form of absorbent strips are arranged on the substrate 210 of the mask 200. At the pattern element 220, the mask 200 has a defect 250 in the form of excess material. To correct the defect 250, a marking 240 is applied on the pattern element 220 in the example illustrated in FIG. 2. The marking 240 is used to determine and compensate for a drift or a displacement of the electron beam 170 with respect to the defect 250 during a repair process of the defect 250.

The marking 240 is deposited after the identification of the defect 250 on the mask 200 for example with the aid of an electron-beam-induced deposition (EBID) process, i.e. with the provision of at least one precursor gas or process gas on the mask 200. It is advantageous if the precursor gas(es) are chosen such that the marking 240 has a different material composition than the pattern elements 220, 230 of the mask 200. In the image of an SEM 160, the marking 240 distinguishes itself not only by way of a topology contrast but additionally by way of a material contrast.

To eliminate the defect 250, an etching reaction is triggered due to an electron beam or particle beam at the location of the defect 250 for example with the provision of a further precursor gas or process gas (or gas mixtures), and the defect 250 is removed therewith. In line with this and with the statements made above with respect to the meaning of the term “working region”, the working region 260 in FIG. 2 is defined substantially by the extent of the defect 250 and is bounded or enclosed by the contour line 265. The working region is indicated here in FIG. 2 merely in a highly schematic fashion. However, as can be clearly seen, in the case of FIG. 2, which shows the prior art, the marking 240 lies outside the working region 260.

A material deposition, for example for correcting a clear defect of the mask 200, would be analogously possible.

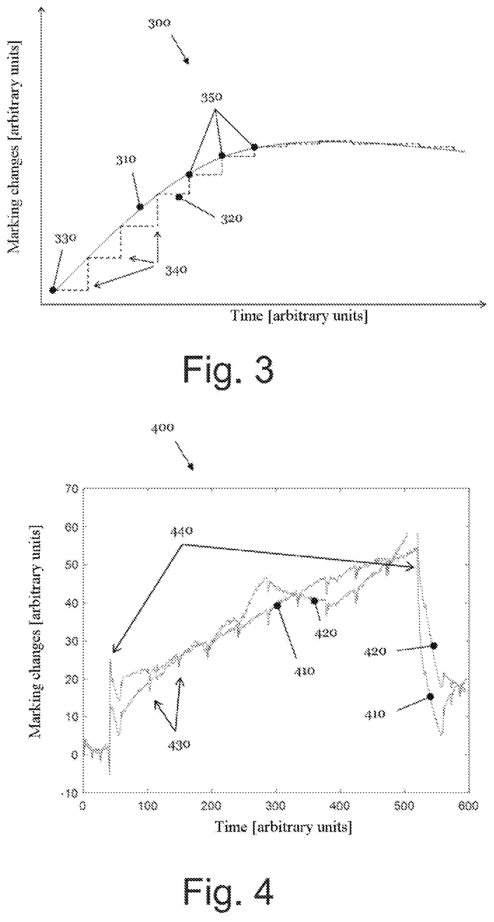

FIG. 3 schematically presents by way of example the compensation of drift or a displacement of an electron beam 170 relative to the marking 240 during a repair process of the defect 250 according to the prior art. A local electrostatic charging of the mask 200 is difficult to define mathematically. This also applies to thermal drift between the electron beam 170 and the marking 240. The effects of electrostatic charging of the mask 200 and/or the displacement thereof relative to the point of incidence of the electron beam 170 are therefore measured and corrected with respect to the marking 240 with periodic time spans. The solid curve 310 in FIG. 3 schematically shows the change, displacement, variation or drift of the marking 240 as a function of time during a repair process of the defect 250.

At the beginning of the repair process, a reference position 330 of the marking 240 is determined. The reference position 330 can be specified relative to a reference marking of the mask 200 or in absolute terms with respect to a coordinate system of the mask 220. In the second step, the position of the repair shape with respect to the marking 240 is defined. The repair of the defect 250 is then begun. For this purpose, one or more etching gases are provided at the location of the defect 250 of FIG. 2, as already mentioned, and the electron beam 170 is scanned, as specified by the repair shape, over the defect 250 and through the working region 260 schematically shown in FIG. 2.

After specific time intervals 320 have passed, the repair process is interrupted with regular or irregular time spans 340, but without interrupting the provision of the precursor gas(es), in order to scan the marking 240 with the electron beam 170. A displacement, drift or change 350 in the marking with respect to the reference marking 330 or relative to the preceding measurement of the marking 240 is determined from the SEM image of the marking 240. Afterwards, the position of the repair shape in relative or absolute terms with respect to the marking 240 is corrected on the basis of the change 350 in the marking and the repair process of the defect 250 is continued.

FIG. 4 shows a further example of a displacement or drift of the marking 240 during a repair process of the defect 250 according to the prior art. Time in arbitrary units is plotted on the x-axis of the diagram 400 in FIG. 4. The number of measurements of the marking 240 during a repair process can also be shown on the abscissa of the diagram 400. The time span between performing two scanning processes can lie in the range from 1 second to 50 seconds. The example illustrated in FIG. 4 indicates a time range of approximately 1000 seconds. The total displacement or drift of the marking 240 in arbitrary units relative to the reference position 330 of the marking 240 is shown on the y-axis of the diagram 400. By way of example, the drift can be specified as the number of scanned pixels of the electron beam 170 in one direction. Depending on the focusing of the electron beam, a pixel can have dimensions in the range of 0.1 nm to 10 nm. The ordinate of the diagram 400 encompasses a position change of approximately 120 nm.

The drift of the marking 240 in the x-direction is shown by the curve 410 in the diagram 400 and the displacement of the marking 240 in the y-direction is shown by the curve 420. Large position changes or position displacements of the marking 240 are brought about by switching between two process or precursor gases. This is illustrated by the arrows 440 in FIG. 4. Smaller swings or jumps in the position change are brought about for example by switching between different repair shapes for repairing the defect 250 (see the arrows 430).

The procedure according to the prior art shown in FIGS. 2 to 4 may be adequate for small defects, such as the defect 250 (it should be noted that the extent of the defect 250 is smaller than the dimensions of the lines 220, 230 and spaces between them, that is to say typically a few nm). However, for large-area defects (for example extents of a few 100 nm), the conditions change significantly.

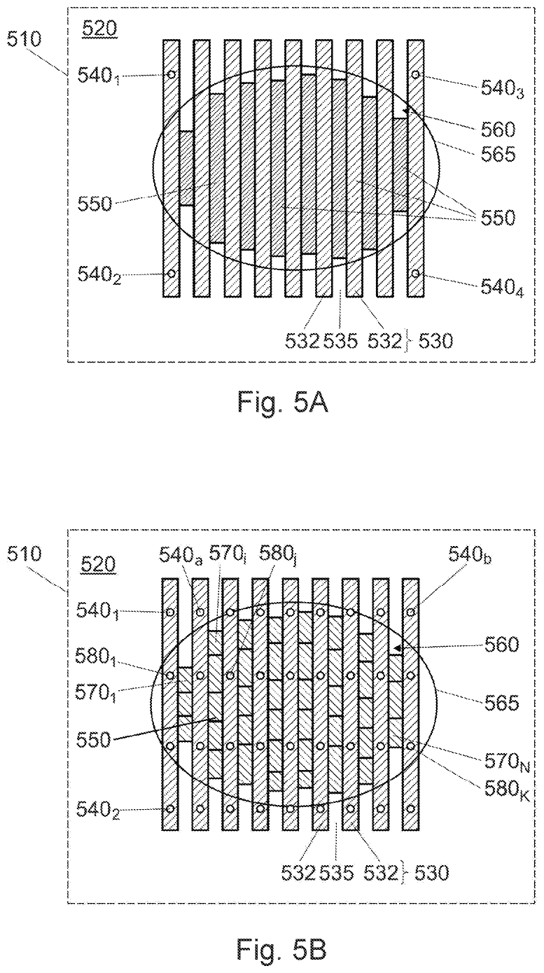

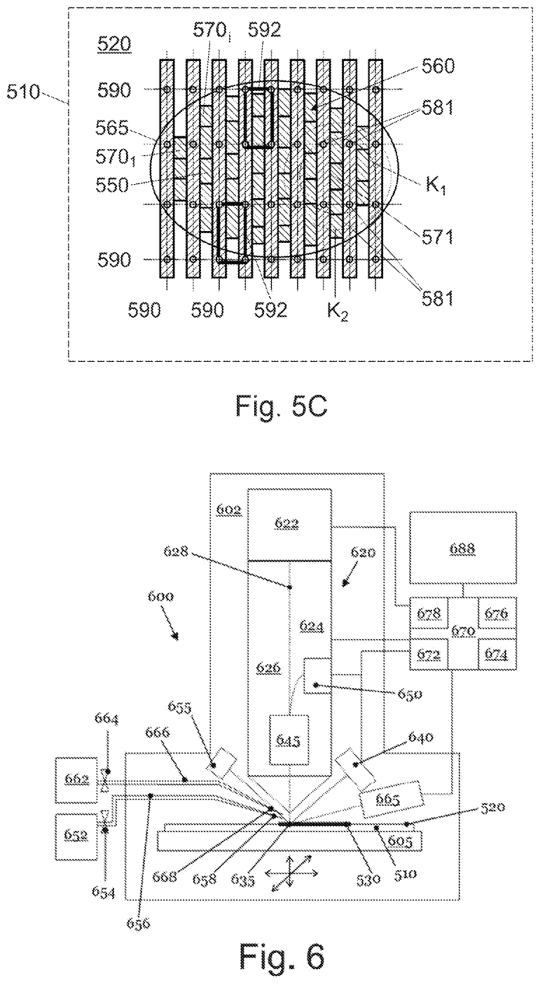

FIGS. 5A-5C therefore show how the present invention, proceeding from the situation known from the prior art, as it is shown in FIG. 5A, can enable, among other things, an increase in accuracy and efficiency of the examination and/or processing of a mask, in particular for large-area, connected defects, by introducing first reference markings in the interior of a working region.

FIG. 5A shows such a large-area, connected defect 550 on the surface 520 of a mask 510, of which in FIGS. 5A-5C only one relevant portion is shown (indicated by the dashed line). The dimensions of the portion shown can be, for example, a few 100 nm, for example in the order of approximately 500×500 nm.

Mask structures 530, which are formed in the example shown by lines and spaces, are located on the mask surface 520, that is to say regions 532 of absorber material arranged next to one another and interposed regions 535 without or with less absorber material are located in alternation on the mask surface 520.

The defect 550, which can be present for example in the form of excess absorber material or in the form of foreign material that contaminates the mask structures 530, extends over these structures. The measure of contamination or the deviation from the target value of the absorber material thickness over the defect can certainly vary in this case. However, the defect 550 should be considered “as a unit” because it is connected or at least is examined or processed in one uniform process operation (for example in contrast to spatially clearly separated defects that are processed in completely independents cycles).

In the case shown here, the defect 550 consequently corresponds to the (simply connected) working region 560. For illustration purposes, a contour line 565 that encloses and bounds the working region 560 is drawn in FIGS. 5A-5C. However, the illustration is here quite schematic, and for the sake of simplicity and clarity, the contour line 565 is shown as an ellipse.

In this situation according to FIG. 5A, which belongs to the prior art, four reference marks 540₁ to 540₄, which can be used as comparison markers for the beam position and thus for example for correcting drift in the manner described above, are located outside the working region 560. However, these markers 540₁ to 540₄ have a distance for example from the center of the working region 560 that is so great that position compensation may no longer be possible without moving the stage if the examination or processing takes place there. This can make the method long and susceptible to errors, among other things.

This problem is addressed by the present invention with its various aspects.

In the case shown in FIG. 5B, which is the result of the application of an embodiment of a method according to the invention in accordance with the first and/or second aspect, the working region 560 was initially divided into a plurality of partial regions 570₁, 570ᵢ, 570_{N}, that is to say into N partial regions, which are numbered using the variable i={1, . . . , N} and are collectively denoted by the number 570. For the sake of clarity, these are shown only in the region of the spaces 535. In the extreme case, only one partial region would also be conceivable (N=1), but a division into two or more partial regions (N≥2) can be preferred, in particular for large-area defects.

Furthermore, a first quantity of first reference markings 580₁, 580ᵢ, 580_{K} were positioned within the working region 560 (i.e. their position was established) and then written onto the mask 510 (e.g. with an electron beam or particle beam, possibly using one or more precursor gases; see in this respect also the statements made below regarding FIG. 6). Thus, there are K of them, which are numbered with the variable j={1, . . . , K} and are collectively denoted by the numeral 580 (wherein K could also be 1). The first reference markings 580 consequently lie within the extent of the defect 550 and can be used as comparison markers in particular for the examination or processing of partial regions 570 located in the interior. For this purpose, at least one of the partial regions 570, preferably at least the partial regions 570 located in the interior of the defect 550, with particular preference all partial regions 570 of the working region 560, is/are assigned one or more of these first reference markings 580. A given first reference marking 580j can also be assigned here to a plurality of partial regions 570 (the same applies to the second reference markings 540).

During the examination or processing of the mask 510, the position of the assigned first reference marking(s) 580 (and possibly also assigned second reference marking(s) 540) are used as comparison markers when the corresponding partial region “is next”, for example to compare a measured beam position with a target position (see also the statements in this respect regarding FIGS. 1 to 4). Since the first reference markings 580 are always present—even when processing the interior of the defect 550—in a local environment of an instantaneous working point (at least under the assumption that the positioning and assignment was selected such that this is the case; see in this respect also FIG. 5C), stage movements are minimized and the method thus becomes more efficient and more accurate.

Outside the working region 560, a second quantity of second reference markings 540₁, 540₂, 540ₐ, 540_{b} were positioned and written onto the mask 510, the number of which will not be taken into account further, except to say that the number can also be 1, but is preferably greater than 1. For example for peripheral partial regions, such as for example the partial regions 570₁ and 570_{N} of FIG. 5B, said second reference markings can complement the first reference markings 580 and be assigned to such peripheral partial regions

It should be noted that in FIGS. 5B and 5C, all reference markings are positioned in the region of the lines 532 and were written there onto the mask 510, which can certainly be preferred because they can there have the smallest or at least less of a negative influence on the mask performance or the like than if they were written into the spaces 535. However, this is not mandatory.

FIG. 5C shows further possibilities and details relating to the positioning and assignment of the reference markings 540, 580.

Initially, FIG. 5C shows a positioning of the reference markings according to an at least approximately regular grid 590, which is made up in the present case from rectangular “unit cells” 592 (i.e. from a regular 4-gon). Other unit cells such as squares or (isosceles, in particular equilateral) triangles are likewise conceivable. Other m-gons or combinations of different m-gons that allow tessellation of the plane are also suitable. What is meant by “approximately regular” can be seen easily in FIG. 5C: individual reference markings 540, 580 are not located perfectly on the grid spaces but slightly next to them, but the deviations from a perfect grid are small compared to distances between the reference markings 540, 580 (e.g. <20%, <10%, <5%, <2% or <1%; see above).

Furthermore, FIG. 5C illustrates the possibility of the assignment of one or two layers of reference markings to a given partial region. By way of example, a partial region was picked in FIG. 5C and denoted by the numeral 571. The procedure described can be used for an arbitrary number of, preferably all partial regions 570.

In the case shown, in addition m=4 closest reference markings (denoted collectively by the numeral 581 for the sake of clarity) and, in addition, n=4 second closest reference markings (for the sake of clarity without a numeral in FIG. 5C) are assigned. The values for m and n can also be chosen differently, and they can also vary from one partial region to the other.

In the present case, m=n=4 was chosen because this corresponds to the shape of the unit cell 592 as a 4-gon, and in this way the symmetry of the arrangement manifests in the number of the assigned reference markings 581. In other words, precisely the number of closest reference markings 581 as are necessary for reproducing the unit cell 592 was chosen. In this way, the additional information contained in the symmetric arrangement (compared with a non-symmetric arrangement) can be used particularly advantageously.

The m=4 closest reference markings were determined here such that, proceeding from the center point/centroid of the partial region 571, a circle K₁ was drawn and its radius was increased until four reference markings, specifically those denoted by 581, fell inside the circle. The n=4 second closest reference markings were determined in the same way with a further circle K₂. Rather than circles, other geometric shapes can also be used for this type of distance determination, for example ellipses or squares (mathematically, this corresponds to the use of different p-norms as the distance measure; a circle here corresponds to the case p=2).

In the present case, all 8 closest and/or second closest reference markings are first reference markings within the working region 560. However, this also depends on the position of the partial region within the working region 560. This would be different for the partial region 570₁, for example. For all the partial regions shown in FIG. 5C, however, at least one of the m=4 closest reference markings would lie within the working region 560, which also represents the preferred case (also for other values of m). However, not all m closest reference markings need to stem from the first quantity of reference markings 580 located within the working region 560; second reference markings 540 may also be involved.

If a degradation of a specific reference marking 540, 580 is detected (for example due to a loss in contrast of the marking in an image of the region of the mask 510 comprising it) and/or already proactively for avoiding such degradations, a re-assignment of the reference markings by excluding the degraded or relevant reference marking can take place for the partial region or regions of the working region 560 to which the degraded/relevant reference marking was assigned (replacing a plurality of markings at once is also analogously possible). For each of the relevant partial regions, the degraded/relevant reference marking can be replaced by the respectively closest reference marking from the first quantity or the second quantity which was not already assigned to the respective partial region. To determine which reference mark this is, again the abovementioned “circle method” can be used, with the relevant partial region (or its centroid) being the center point of the circle. In this way, for example, the losses in efficiency caused by the degradation can be contained, or a degradation can be avoided entirely or at least substantially with a provisional full exchange of the reference markings.

FIG. 6 schematically shows, in section, a few components of an apparatus 600, on which embodiments of the method according to the invention for examining and/or processing a mask (or generally one of the objects mentioned in the introductory part, for which the present invention can be used) can take place and be implemented. By way of example, reference is made in FIG. 6 and the description that will now follow to the mask 510 of FIGS. 5A-5C, although this is not to be understood in a limiting manner. Other lithographic masks or objects can be used instead

The apparatus 600 comprises a vacuum chamber 602 and, therein, a scanning particle microscope 620. In the example of FIG. 6, the scanning particle microscope 620 is a scanning electron microscope (SEM) 620. An electron beam as a particle beam has the advantage that the mask 510 to be examined or processed substantially cannot be damaged, or can be damaged only to a slight extent, by said beam. However, other charged particle beams are also possible, for instance an ion beam of an FIB (focused ion beam) system (not illustrated in FIG. 6).

The SEM 620 comprises as essential components a particle gun 622 and a column 624, in which the electron optical unit or beam optical unit 626 is arranged. The electron gun 622 produces an electron beam 628 and the electron or beam optical unit 626 focuses the electron beam 628 and directs it at the output of the column 624 onto the mask 510 (or generally at a lithographic sample or object). The mask 510 has a surface 520 with a structure or structures 530, as was already explained in detail above. A surface charge that may be present on the mask 510 is not illustrated in FIG. 6.

The mask 510 is arranged on a sample stage 605. As symbolized by the arrows in FIG. 6, the sample stage 605 can be moved in three spatial directions relative to the electron beam 628 of the SEM 620.

A spectrometer-detector combination 640 discriminates the secondary electrons generated by the electron beam 628 at the measurement point 635 and/or electrons back-scattered by the mask 510 on the basis of their energy and then converts them into an electrical measurement signal. The measurement signal is then passed on to an evaluation unit 676 of the computer system 670.

To separate energy, the spectrometer-detector combination 640 can contain a filter or a filter system in order to discriminate the electrons in the energy (not illustrated in FIG. 6).

Like the spectrometer-detector combination 640, energy-resolving spectrometers can be arranged outside the column 624 of the SEM 620. However, it is also possible to arrange a spectrometer and the associated detector in the column 624 of an SEM 620. In the example illustrated in FIG. 6, a spectrometer 645 and a detector 650 are incorporated in the column 624 of an SEM 620. In addition or as an alternative to the spectrometer-detector combination 640, the spectrometer 645 and the detector 650 can be used in the apparatus 600.

Furthermore, the apparatus 600 in FIG. 6 can optionally comprise a detector 655 for detecting the photons generated by the incident electron beam 628 at the measurement point 635. The detector 655 can for example spectrally resolve the energy spectrum of the generated photons and thereby allow conclusions to be drawn concerning the composition of the surface 520 or layers near the surface of the mask 510.

In addition, the apparatus 600 can comprise an ion source (not illustrated), which provides low-energy ions in the region of the measurement point 635 for the event that the mask 510 or its surface 520 is electrically insulating or semiconducting and has a negative surface charge. With the aid of the ion source, a negative charging of the mask surface 520 can be reduced locally and in a controlled manner.

Should the mask surface 520 have an undesired distribution of positive surface charges, caused for instance by the handling of the mask 510, the electron beam 628 can be used to reduce the charge of the mask surface 520.

The computer system 670 comprises a scanning unit 672, which scans the electron beam 628 over the mask 510 and in particular over the markings 540, 580 and/or the defect 550. The scanning unit 672 controls deflection elements in the column 624 of the SEM 620, which are not illustrated in FIG. 6. Furthermore, the computer system 670 comprises a setting unit 674 in order to set and control the various parameters of the SEM 620. Parameters that are settable by the setting unit 674 can be for example: the magnification, the focus of the electron beam 628, one or more settings of the stigmator, the beam displacement, the position of the electron source and/or one or more stops (not illustrated in FIG. 6).

The scanning unit 672 and/or the setting unit 674 can perform or control or contribute to for example an examination and/or processing of the mask 510 in the working region 560 with the use of an embodiment of the method according to the invention.

Moreover, the computer system 670 comprises a memory unit 676, in which for example instructions for performing an embodiment of one of the methods according to the invention can be stored. The computer system 670 can comprise one or more processors which are designed to implement such instructions, that is to say the corresponding components of the apparatus 600 (for example the SEM 620, the scanning unit 672, the setting unit 674 and/or the gas feed system yet to be described) in accordance with the commands. The processor can comprise a powerful graphics processor, for example.

The computer system 670 in FIG. 6 can be integrated into the apparatus 600 or it can be embodied as a dedicated device. The computer system 670 can be embodied using hardware, software, firmware or a combination.

For processing the defect 550 of the mask 510 and/or for writing (first and/or second) reference markings 540 and/or 560 onto the mask 510, the apparatus 600 of FIG. 6 preferably has a plurality of different storage containers for different process or precursor gases. In the apparatus 600 given by way of example, two storage containers are illustrated. However, an apparatus 600 can also have more than two storage containers for processing the mask 510 and/or writing reference markings 540, 580 onto the mask 510. The first storage tank 652 stores a precursor gas or a deposition gas, which can be used to act together with the electron beam 628 of the SEM 620 for depositing material or for producing a reference marking 540, 580 of the mask 510. Moreover, the electron beam 628 of the SEM 620 can be used for example for depositing missing absorber material of one of the pattern elements of the mask 510. The second storage tank 662 contains an etching gas, with the aid of which the defect 550 can be etched, for example.

Each storage container 652, 662 is equipped with its own valve 654 and 664, respectively, to control the amount of gas particles provided per unit time or the gas flow rate at the location of incidence 635 of the electron beam 628 on the surface 520 of the mask 510. Furthermore, the two storage containers 652, 662 have their own gas feeds 656, 666, which end with a nozzle 658, 668 near the point of incidence 635 of the electron beam 628 on the mask 510. In the apparatus 600 that is illustrated by way of example in FIG. 6, the valves 654, 664 are incorporated in the vicinity of the storage containers. In an alternative embodiment, the valves 654, 664 can be arranged in the vicinity of the corresponding nozzle 658 and 668, respectively (not shown in FIG. 6). Each storage container 652, 662 can have its own element for individual temperature setting and control. The temperature setting facilitates both cooling and heating for each precursor gas. In addition, the gas feeds 656, 666 can likewise respectively have their own element for setting and monitoring the temperature at which each precursor gas is provided at the reaction location (likewise not shown in FIG. 6).

The apparatus 600 in FIG. 6 can comprise a pump system to produce and maintain the required vacuum. The pump system is not shown in FIG. 6 for reasons of clarity. In addition, the apparatus 600 can comprise a suction extraction apparatus (likewise not illustrated in FIG. 6). The suction extraction apparatus in combination with a pump or a pump system makes it possible that the fragments or constituents that are produced during the decomposition of a precursor gas and are not required for the local chemical reaction are extracted from the vacuum chamber 602 of the apparatus 600 substantially at the point of origin. Since the gas constituents that are not required are pumped away locally at the location of incidence of the electron beam 628 on the mask 510 out of the vacuum chamber 602 of the apparatus 600 before they can be distributed and settle in it, contamination of the vacuum chamber 602 is prevented.

In the following further embodiments of the invention are described.

Embodiment 1: A method for examining and/or processing a lithographic object, in particular a photomask, with a beam of charged particles in a working region on the object, comprising:
a. dividing the working region into a set of partial regions; and
b. positioning a first quantity of first reference markings over the working region so that the first quantity of first reference markings lie within the working region.

Embodiment 2: Method according to embodiment 1, furthermore comprising, for at least one partial region of the working region, preferably for each of the partial regions of the working region:
assigning at least one reference marking from the first quantity to the respective partial region.

Embodiment 3: Method according to embodiment 1 or 2, further comprising writing the first quantity of first reference markings onto the object, preferably by use of the beam of charged particles.

Embodiment 4: Method according to any of embodiments 1-3, further comprising positioning a second quantity of second reference markings on the object, wherein the second quantity of second reference markings lie outside the working region.

Embodiment 5: Method according to embodiment 4, furthermore comprising, for at least one of the partial regions of the working region:
assigning at least one reference marking from the second quantity to the respective partial region.

Embodiment 6: Method according to embodiment 4 or 5, further comprising writing the second quantity of second reference markings onto the object, preferably by use of the beam of charged particles.

Embodiment 7: Method according to any of embodiment 1-6 in combination with embodiment 2 or embodiment 5, wherein assigning comprises, for at least one of the partial regions of the working region, preferably for all partial regions of the working region:
assigning the m closest reference markings to the respective partial region, wherein preferably m=3, with particular preference m=4.

Embodiment 8: Method according to embodiment 7, wherein, for each respective partial region, at least one of the assigned m closest reference markings stems from the first quantity of first reference markings located within the working region.

Embodiment 9: Method according to embodiment 7 or 8, furthermore comprising, for at least one of the partial regions of the working region, preferably for all partial regions:
assigning the n second closest reference markings to the respective partial region, wherein preferably n=3, with particular preference n=4.

Embodiment 10: Method according to any of embodiments 1-9, wherein positioning the first quantity of first reference markings and/or the second quantity of second reference markings takes place in accordance with an at least approximately regular, two-dimensional grid.

Embodiment 11: Method according to embodiment 10 in combination with any of embodiments 7-9, wherein a unit cell of the grid represents an m-gon.

Embodiment 12: Method for examining and/or processing a lithographic object, in particular a photomask, with a beam of charged particles in a working region on the object, comprising:
a. assigning at least one reference marking from a first quantity of first preference markings, which are distributed over the working region and lie within the working region, to at least one partial region from a set of partial regions into which the working region is divided; and
b. performing the examination and/or processing of the object in the at least one partial region while taking into account the position of the assigned at least one reference marking.

Embodiment 13: Method according to embodiment 12, wherein each partial region from the set of partial regions in step a. is assigned at least one reference marking from the first quantity, and the method further comprises performing the examination and/or processing of the object in all partial regions while taking into account the position of the at least one reference marking assigned to the respective partial region.

Embodiment 14: Method according to embodiment 12 or 13, further comprising dividing the working region into the set of partial regions.

Embodiment 15: Method according to any of embodiments 12-14, further comprising positioning the first quantity of first reference markings over the working region.

Embodiment 16: Method according to any of embodiments 12-15, further comprising writing the first quantity of first reference markings onto the object, preferably by use of the beam of charged particles.

Embodiment 17: Method according to any of embodiments 12-16, furthermore comprising, for at least one of the partial regions of the working region:
assigning at least one reference marking from a second quantity of second reference markings to the respective partial region, wherein the second quantity of second reference markings lie outside the working region; and
performing the examination and/or processing of the object in the respective partial region while also taking into account the position of the at least one second reference marking assigned to said partial region.

Embodiment 18: Method according to embodiment 17, further comprising positioning the second quantity of second reference markings on the object.

Embodiment 19: Method according to embodiment 17 or 18, further comprising writing the second quantity of second reference markings onto the object, preferably by use of the beam of charged particles.

Embodiment 20: Method according to any of embodiments 12-19, wherein assigning comprises, for at least one of the partial regions of the working region, preferably for all partial regions of the working region:
assigning the m closest reference markings to the respective partial region, wherein preferably m=3, with particular preference m=4.

Embodiment 21: Method according to embodiment 20, wherein, for each respective partial region, at least one of the assigned m closest reference markings stems from the first quantity of first reference markings located within the working region.

Embodiment 22: Method according to embodiment 20 or 21, furthermore comprising, for at least one of the partial regions of the working region, preferably for all partial regions:
assigning the n second closest reference markings to the respective partial region, wherein preferably n=3, with particular preference n=4.

Embodiment 23: Method according to any of embodiments 12-22 in combination with embodiment 15 or embodiment 18, wherein positioning the first quantity of first reference markings and/or the second quantity of second reference markings takes place in accordance with an at least approximately regular, two-dimensional grid.

Embodiment 24: Method according to embodiment 23 in combination with any of embodiments 20-22, wherein a unit cell of the grid represents an m-gon.

Embodiment 25: Method according to any of embodiments 12-24, wherein the position of the reference marking(s) assigned to a respective partial region is taken into account such that it serves for compensating for any drift of the beam of charged particles during the examination and/or processing of the partial region.

Embodiment 26: Method according to embodiment 25, wherein compensating for the drift comprises comparing a measured position of a respective reference marking with a target position of said reference marking.

Embodiment 27: Method according to any of embodiments 12-26, wherein if a specific reference marking has been identified as being degraded, the reference markings are re-assigned by excluding the degraded reference marking for the partial region or regions of the working region to which the degraded reference marking was assigned.

Embodiment 28: Method according to embodiment 27, wherein, for each of the relevant partial regions, the degraded reference marking is replaced by the respectively closest reference marking from the first quantity or the second quantity which was not already assigned to the respective partial region.

Embodiment 29: Apparatus for examining and/or processing a lithographic object, in particular a photomask, with a beam of charged particles in a working region on the object, comprising:
a. means for dividing the working region into a set of partial regions; and
b. means for positioning a first quantity of first reference markings over the working region so that the first quantity of first reference markings lie within the working region.

Embodiment 30: Apparatus according to embodiment 29, wherein the apparatus is configured to carry out the method according to any of embodiments 1-11.

Embodiment 31: Apparatus for examining and/or processing a lithographic object, in particular a photomask, with a beam of charged particles in a working region on the object, comprising:
a. means for assigning at least one reference marking from a first quantity of first preference markings, which are distributed over the working region and lie within the working region, to at least one partial region from a set of partial regions into which the working region is divided; and
b. means for performing the examination and/or processing of the object in the at least one partial region while taking into account the position of the assigned at least one reference marking.

Embodiment 32: Apparatus according to embodiment 31, wherein the apparatus is configured to carry out the method according to any of embodiments 12-28.

Embodiment 33: Computer program comprising commands that, upon execution, cause the apparatus according to embodiment 29 or 30 to carry out the method steps of the method according to any of embodiments 1-11, or cause the apparatus according to embodiment 31 or 32 to carry out the method steps of the method according to any of embodiments 12-28.

What is claimed is:

1. A method for processing a defect of a lithographic object, in particular a photomask, with a beam of charged particles in a working region on the object, the method comprising:
a. dividing the working region into a set of one or more partial regions; and
b. positioning a first quantity of first reference markings over the working region so that the first quantity of first reference markings lie within the working region;
wherein the working region is defined substantially by an extent of the defect and can comprise one or more gaps in which processing takes place to a smaller extent or no processing is intended.

2. The method of claim 1, furthermore comprising, for at least one partial region of the working region:
assigning at least one reference marking from the first quantity to the respective partial region.

3. The method of claim 1, further comprising writing the first quantity of first reference markings onto the object.

4. The method of claim 1, further comprising positioning a second quantity of second reference markings on the object, wherein the second quantity of second reference markings lie outside the working region.

5. The method of claim 4, furthermore comprising, for at least one of the partial regions of the working region:
assigning at least one reference marking from the second quantity to the respective partial region.

6. The method of claim 4, further comprising writing the second quantity of second reference markings onto the object.

7. The method of claim 1,
comprising, for at least one partial region of the working region: assigning at least one reference marking from the first quantity to the respective partial region, wherein assigning comprises, for at least one of the partial regions of the working region:
assigning the m closest reference markings to the respective partial region, wherein m is an integer greater than 1.

8. The method of claim 7, wherein, for each respective partial region, at least one of the assigned m closest reference markings stems from the first quantity of first reference markings located within the working region.

9. The method of claim 7, furthermore comprising, for at least one of the partial regions of the working region:
assigning the n second closest reference markings to the respective partial region, wherein n is an integer greater than 1.

10. The method of claim 4, wherein positioning the first quantity of first reference markings and/or the second quantity of second reference markings takes place in accordance with an at least approximately regular, two-dimensional grid.

11. The method of claim 10, comprising, for at least one partial region of the working region: assigning at least one reference marking from the first quantity to the respective partial region, wherein assigning comprises, for at least one of the partial regions of the working region: assigning the m closest reference markings to the respective partial region, wherein m is an integer greater than 2, wherein a unit cell of the grid represents an m-gon.

12. A method for processing a defect of a lithographic object, in particular a photomask, with a beam of charged particles in a working region on the object, comprising:
a. dividing the working region into a set of two or more partial regions;
b. assigning at least one reference marking from a first quantity of first reference markings for the object to at least two partial regions from the set of two or more partial regions;
wherein to one of the at least two partial regions at least one reference marking is assigned which differs from the reference marking that is assigned to another one of the at least two partial regions; and
c. performing the processing of the object in the at least two partial regions while taking into account the position of each of the assigned at least one reference marking.

13. The method of claim 12, wherein the working region comprises a first partial region and a second partial region, wherein the second partial region is adjacent to the first partial region.

14. The method of claim 12, wherein the first quantity of first reference markings is positioned over the working region and lies within the working region.

15. The method of claim 12, wherein each partial region from the set of partial regions in step b. is assigned at least one reference marking from the first quantity, and the method further comprises performing the examination and/or processing of the object in all partial regions while taking into account the position of the at least one reference marking assigned to the respective partial region.

16. The method of claim 12, further comprising positioning the first quantity of first reference markings over the working region.

17. The method of claim 12, further comprising writing the first quantity of first reference markings onto the object.

18. The method of claim 12, furthermore comprising, for at least one of the partial regions of the working region:
assigning at least one reference marking from a second quantity of second reference markings to a respective partial region, wherein the second quantity of second reference markings lie outside the working region; and
performing the processing of the object in the respective partial region while also taking into account the position of the at least one second reference marking assigned to said partial region.

19. The method of claim 18, further comprising positioning the second quantity of second reference markings on the object.

18. The method of claim 18, further comprising writing the second quantity of second reference markings onto the object.

21. The method of claim 12, wherein assigning comprises, for at least one of the partial regions of the working region:
assigning the m closest reference markings to the respective partial region, wherein m is an integer greater than 1.

22. The method of claim 21, wherein, for each of the respective partial region, at least one of the assigned m closest reference markings stems from the first quantity of first reference markings located within the working region.

23. The method of claim 21, furthermore comprising, for at least one of the partial regions of the working region:
assigning the n second closest reference markings to the respective partial region, wherein n is an integer greater than 1.

24. The method of claim 18, further comprising positioning the first quantity of first reference markings over the working region, wherein positioning the first quantity of first reference markings and/or the second quantity of second reference markings takes place in accordance with an at least approximately regular, two-dimensional grid.

25. The method of claim 24, wherein assigning comprises, for at least one of the partial regions of the working region: assigning the m closest reference markings to the respective partial region, wherein m is an integer greater than 2, wherein a unit cell of the grid represents an m-gon.

26. The method of claim 12, wherein the position of the reference marking(s) assigned to a respective partial region is taken into account such that it serves for compensating for any drift of the beam of charged particles during the processing of the partial region.

27. The method of claim 26, wherein compensating for the drift comprises comparing a measured position of a respective reference marking with a target position of said reference marking.

28. The method of claim 12, wherein if a specific reference marking has been identified as being degraded, the reference markings are re-assigned by excluding the degraded reference marking for the partial region or regions of the working region to which the degraded reference marking was assigned.

29. The method of claim 28, wherein, for each of the relevant partial regions, the degraded reference marking is replaced by the respectively closest reference marking from the first quantity or the second quantity which was not already assigned to the respective partial region.

30. An apparatus for processing a defect of a lithographic object, in particular a photomask, with a beam of charged particles in a working region on the object, the apparatus comprising:
a. means for dividing the working region into a set of one or more partial regions; and
b. means for positioning a first quantity of first reference markings over the working region so that the first quantity of first reference markings lie within the working region;
wherein the working region is defined substantially by an extent of the defect and can comprise one or more gaps in which processing takes place to a smaller extent or no processing is intended.

31. The apparatus of claim 30, wherein the apparatus is configured to carry out a method for processing a defect of a lithographic object, with a beam of charged particles in a working region on the object, the method comprising:
dividing the working region into a set of one or more partial regions; and
positioning a first quantity of first reference markings over the working region so that the first quantity of first reference markings lie within the working region;
wherein the working region is defined substantially by an extent of the defect and can comprise one or more gaps in which processing takes place to a smaller extent or no processing is intended.

32. An apparatus for processing a lithographic object, with a beam of charged particles in a working region on the object, comprising:
a. means for dividing the working region into a set of two or more partial regions;
b. means for assigning at least one reference marking from a first quantity of first reference markings for the object to at least two partial regions from the set of two or more partial regions,
wherein to one of the at least two partial regions at least one reference marking is assigned which differs from the reference marking that is assigned to another one of the at least two partial regions;
c. means for performing the processing of the object in the at least two partial regions while taking into account the position of each of the assigned at least one reference marking.

33. The apparatus of claim 32, wherein the apparatus is configured to carry out a method for processing a defect of a lithographic object, with a beam of charged particles in a working region on the object, the method comprising:
dividing the working region into a set of two or more partial regions;
assigning at least one reference marking from a first quantity of first reference markings for the object to at least two partial regions from the set of two or more partial regions;
wherein to one of the at least two partial regions at least one other reference marking is assigned than to another of the at least two partial regions.

34. A computer program comprising commands that, upon execution, cause a first apparatus to carry out method steps of a first method, or cause a second apparatus to carry out method steps of a second method;
wherein the first apparatus is for processing a defect of a lithographic object, with a beam of charged particles in a working region on the object; wherein the first apparatus comprises: means for dividing the working region into a set of one or more partial regions; and means for positioning a first quantity of first reference markings over the working region so that the first quantity of first reference markings lie within the working region; wherein the working region is defined substantially by an extent of the defect and can comprise one or more gaps in which processing takes place to a smaller extent or no processing is intended;
wherein the first method is for processing a defect of a lithographic object, with a beam of charged particles in a working region on the object, wherein the first method comprises: dividing the working region into a set of one or more partial regions; and positioning a first quantity of first reference markings over the working region so that the first quantity of first reference markings lie within the working region; wherein the working region is defined substantially by an extent of the defect and can comprise one or more gaps in which processing takes place to a smaller extent or no processing is intended;
wherein the second apparatus is for processing a lithographic object, with a beam of charged particles in a working region on the object, wherein the second apparatus comprises: means for dividing the working region into a set of two or more partial regions; means for assigning at least one reference marking from a first quantity of first reference markings for the object to at least two partial regions from the set of two or more partial regions; wherein one of the at least two partial regions at least one other reference marking is assigned to than to another of the at least two partial regions; and means for performing the processing of the object in the at least two partial regions while taking into account the position of each of the assigned at least one reference marking;
wherein the second method is for processing a defect of a lithographic object, with a beam of charged particles in a working region on the object, wherein the second method comprises: dividing the working region into a set of two or more partial regions; assigning at least one reference marking from a first quantity of first reference markings for the object to at least two partial regions from the set of two or more partial regions; wherein to one of the at least two partial regions at least one other reference marking is assigned than to another of the at least two partial regions; and performing the processing of the object in the at least two partial regions while taking into account the position of each of the assigned at least one reference marking.

35. The method of claim 7, comprising writing the first quantity of first reference markings onto the object, wherein assigning the m closest reference markings to the respective partial region comprises assigning the four closest reference markings to the respective partial region.
